(19) United States
(12) Patent Application Publication
(10) Pub. No.: US 2023/0157145 A1
(43) Pub. Date: May 18, 2023

(54) OLED DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Feng XU, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/966,065

(22) PCT Filed: Mar. 17, 2020
(86) PCT No.: PCT/CN2020/079606

§ 371 Date: Jul. 30, 2020

(30) Foreign Application Priority Data
Dec. 25, 2019 (CN) 201911352582.9

(51) Int. Cl. H10K 77/10; H10K 59/12

(52) U.S. Cl. CPC H10K 77/111; H10K 59/1201; H10K 59/12; H10K 59/40

(57) ABSTRACT

The present invention provides an OLED display panel. The OLED display panel includes an OLED display layer and a substrate bonded to the OLED display layer. The substrate includes a glass substrate, an organic hardened layer, and a transparent conductive layer. The organic hardened layer is disposed on a side of the glass substrate, and the transparent conductive layer is disposed on another side of the glass substrate opposite to the organic hardened layer. The organic hardened layer, the glass substrate, and the transparent conductive layer are an integrated structure.

### FIELD OF INVENTION

The present invention relates to the field of display technologies, and in particular, to an organic light-emitting diode (OLED) display panel and a manufacturing method thereof.

### BACKGROUND OF INVENTION

Display panels, such as organic light-emitting diodes (OLEDs), have received great attention from academics and industries because of their huge development potential in a direction of solid-state lighting and flat-panel displays. OLED panels can be made lighter and thinner, so flexible display technologies will be a future development trend. For the flexible display technologies, thinning an overall structure is an important technical route. From a perspective of material science, reducing use of functional film layers is not only conducive to a reduction of overall structure, but can also reduce use of adhesive layers and reduce interfaces between the film layers. This is very helpful for improving stability of precision flexible display structures. On the other hand, structural strength is also a factor that needs to be considered. Use of all-organic materials to form a stacked structure is often insufficient in strength.

At present, problems of outermost protective layers of flexible OLED display devices have not been solved well. Use of hardened organic materials as protective layers is preferred by the industry. A difficulty is that it is difficult to balance bending performance and protective performance. In general, hardened organic layers are far less effective than glass protective layers as the protective layers.

Therefore, thinning the overall structure through an integrated structure is an important route for development of flexible display technologies. The integrated structure is not only conducive to thinning a structure, but also reduces the use of adhesive layers and reduces the number of interfaces, which is very important for improving stability of the structure.

### TECHNICAL PROBLEM

The present invention provides an OLED display panel and a manufacturing method thereof, which use ultra-thin bendable glass materials, combined with integrated technologies, to propose a new film structure design idea. Through structural improvements, a new flexible OLED display device with an integrated structure is provided to solve current problems.

### Technical Solution

In order to solve the above problems, technical solutions provided by the present invention are as follows:

An embodiment of the present invention provides an organic light-emitting diode (OLED) display panel, comprising:
an OLED display layer; and
a substrate bonded to the OLED display layer;
wherein the substrate comprises a glass substrate, an organic hardened layer, and a transparent conductive layer, the organic hardened layer is disposed on a first side of the glass substrate, the transparent conductive layer is disposed on a second side of the glass substrate, and the first side of the glass substrate is opposite to the second side of the glass substrate;
wherein the organic hardened layer, the glass substrate, and the transparent conductive layer are an integrated structure; and
wherein a thickness of the transparent conductive layer ranges from 1 µm to 10 µm, and a thickness of the organic hardened layer ranges from 10 µm to 100 µm.

The OLED display panel according to the embodiment of the present invention, the OLED display panel further comprises a touch screen circuit disposed on the transparent conductive layer.

The OLED display panel according to the embodiment of the present invention, a material of the organic hardened layer comprises acrylic material or siloxane-based material.

The OLED display panel according to the embodiment of the present invention, the transparent conductive layer is bonded to the OLED display layer.

An embodiment of the present invention further provides an OLED display panel. The OLED display panel comprises:
an OLED display layer; and
a substrate bonded to the OLED display layer;
wherein the substrate comprises a glass substrate, an organic hardened layer, and a transparent conductive layer, the organic hardened layer is disposed on a first side of the glass substrate, the transparent conductive layer is disposed on a second side of the glass substrate, and the first side of the glass substrate is opposite to the second side of the glass substrate; and
wherein the organic hardened layer, the glass substrate, and the transparent conductive layer are an integrated structure.

The OLED display panel according to the embodiment of the present invention, the OLED display panel further comprises a touch screen circuit disposed on the transparent conductive layer.

The OLED display panel according to the embodiment of the present invention, a thickness of the transparent conductive layer ranges from 1 µm to 10 µm.

The OLED display panel according to the embodiment of the present invention, a thickness of the organic hardened layer ranges from 10 µm to 100 µm.

The OLED display panel according to the embodiment of the present invention, a material of the organic hardened layer comprises acrylic material or siloxane-based material.

The OLED display panel according to the embodiment of the present invention, the transparent conductive layer is bonded to the OLED display layer.

An embodiment of the present invention further provides a manufacturing method of the OLED display panel, comprising following steps:
coating an organic hardened layer on a side of a glass substrate, and processing to harden the organic hardened layer;
forming a transparent conductive layer on another side of the glass substrate;
forming a touch screen circuit on the transparent conductive layer; and
bonding an OLED display layer on the transparent conductive layer.

The OLED display panel according to the embodiment of the present invention, a thickness of the organic hardened layer ranges from 10 µm to 100 µm.

The OLED display panel according to the embodiment of the present invention, a thickness of the transparent conductive layer ranges from 1 µm to 10 µm.

The OLED display panel according to the embodiment of the present invention, the organic hardened layer, the glass substrate, and the transparent conductive layer are an integrated structure, and the glass substrate is disposed between the organic hardened layer and the transparent conductive layer.

### Beneficial Effect

According to an OLED display panel and a manufacturing method thereof provided by an embodiment of the present invention, by using an ultra-thin glass substrate, an organic hardened layer and a transparent conductive layer are respectively formed on both sides of the glass substrate, thereby realizing an integrated structure of a cover plate, an ultra-thin glass, and a touch screen. The ultra-thin glass in a flexible structure can improve strength performance of an entire structure, and the glass substrate as a substrate of the transparent conductive layer can improve stability of a touch layer.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a schematic structural view of an OLED display panel provided by the present invention.

FIG. 2 is a flowchart of a manufacturing method of the OLED display panel according to an embodiment of the present invention.

FIG. 3 is a schematic view of a structure of a substrate provided by an embodiment of the present invention.

### DETAILED DESCRIPTION OF PREFERRED EMBODIMENTS

The present invention will be further described in detail below with reference to the accompanying drawings and embodiments. In particular, the following examples are only intended to illustrate the invention, but do not limit the scope of the invention. In the same manner, the following embodiments are only partial embodiments rather than all embodiments of the present invention, and all other embodiments obtained by those skilled in the art without creative efforts are within the scope of the present invention.

In the description of the present invention, it is to be understood that the terms “center,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” and the like are used in the orientations and positional relationships indicated in the drawings for convenience in describing the present invention and for simplicity in description, and are not intended to indicate or imply that the referenced devices or elements must have a particular orientation, be constructed in a particular orientation, and be operated in a particular manner, and are not to be construed as limiting the present invention. Furthermore, the terms “first” and “second” are used for descriptive purposes only and are not to be construed as indicating or implying relative importance or implicitly indicating the number of technical features indicated. Thus, features defined as “first”, “second”, may explicitly or implicitly include one or more of the described features. In the description of the present application, “plurality” means two or more unless specifically limited otherwise.

In the description of the present invention, it is to be noted that, unless otherwise explicitly specified or limited, the terms “mounted,” “connected,” and “linked” are to be construed broadly, e.g., as meaning either a fixed connection, a removable connection, or an integral connection; may be mechanically connected, may be electrically connected or may be in communication with each other; either directly or indirectly through intervening media, either internally or in any other relationship. The specific meaning of the above terms in the present invention can be understood by those of ordinary skill in the art as appropriate.

In the present invention, unless otherwise specifically defined and defined, the first feature is “on” or “under” the second feature may include that the first feature is in direct contact to the second feature, and may also include that the first feature and the second feature are not in direct contact but through additional features between them. Moreover, the first feature is “on,” “above,” and “under” the second feature includes the first feature is directly above and obliquely above the second feature, or merely indicating that the high of the first feature is higher than the second feature. The first feature is “below,” “under,” and “lower” the second feature includes the first feature is directly below and obliquely below the second feature, or merely indicating that the high of the first feature is less than the second feature.

The following disclosure provides many different embodiments or examples for implementing different features of the invention. In order to simplify the disclosure of the present invention, specific example components and arrangements are described below. Of course, they are merely examples and are not intended to limit the present invention. Moreover, the present invention may repeat reference numerals and/or letters in the various examples, such repetition is for the purpose of simplicity and clarity and does not in itself dictate a relationship between the various embodiments and/or configurations discussed. In addition, examples of various specific processes and materials are provided herein, but one of ordinary skill in the art may recognize applications of other processes and/or uses of other materials.

The present invention provides an organic light-emitting diode (OLED) display panel and a manufacturing method thereof, which use ultra-thin bendable glass materials, combined with integrated technologies, to propose a new film structure design idea. Through structural improvements, a new flexible OLED display device with an integrated structure is provided to solve current problems.

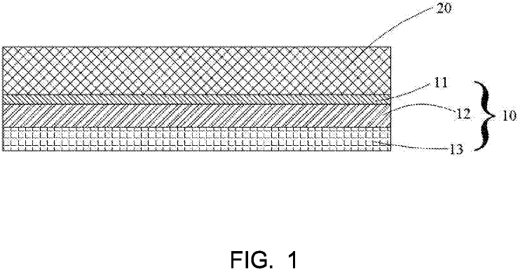

Shown in FIG. 1 is a schematic structural view of an OLED display panel provided by the present invention.

The OLED display panel comprises an OLED display layer 20 and a substrate 10 bonded to the OLED display layer 20.

The substrate 10 comprises a glass substrate 12, an organic hardened layer 13, and a transparent conductive layer 11. The organic hardened layer 13 is disposed on a first side of the glass substrate 12, the transparent conductive layer 11 is disposed on a second side of the glass substrate 12, and the first side of the glass substrate 12 is opposite to the second side of the glass substrate 12.

Wherein the organic hardened layer 13, the glass substrate 12, and the transparent conductive layer 11 are an integrated structure.

The OLED display layer 20 comprises other structural layers such as a buffer layer, a TFT component layer, an OLED element layer, a protective layer, and a packaging layer.

The transparent conductive layer 11 in the substrate 10 is bonded to the OLED display layer 20, or the transparent conductive layer 11 in the substrate 10 is laminated with the OLED display layer 20.

The glass substrate 12 is made of ultra-thin glass. An organic layer of a certain thickness is coated on one side of the glass substrate 12 by a coating method, and then the organic layer is hardened by a hardening technology to form the organic hardened layer 13. The integrated structure of the glass substrate 12 and the organic hardened layer 13 is realized by the hardening technology. A material of the organic hardened layer comprises acrylic material or siloxane-based material. The organic material such as the acrylic material or the siloxane-based material has a certain hardness after being hardened by a hardening technology, which can prevent direct impact on the ultra-thin glass substrate and can well protect the ultra-thin glass substrate 12. A thickness of the organic hardened layer 13 can be set to range from 10 µm to 100 µm, so that the organic hardened layer 13 has a certain strength and can effectively protect the ultra-thin glass substrate 12.

The transparent conductive layer 11 is on the other side of the glass substrate 12 opposite to the organic hardened layer 13. A transparent conductive material having a certain thickness is sputtered on the other side of the glass substrate 12 by a deposition technology or a sputtering technology to form the transparent conductive layer 11. Then, a touch screen circuit is formed on the transparent conductive layer 11, and a touch function is implemented on the transparent conductive layer 11. The transparent conductive layer 11 is made of indium tin oxide (ITO) material or other transparent conductive materials. A thickness of the transparent conductive layer 11 is controlled between 1 µm and 10 µm. Implementing the touch function on the transparent conductive layer 11 can integrate the ultra-thin glass substrate 12 with a touch circuit. Moreover, using the glass substrate 12 as the base material of the transparent conductive layer 11 can improve stability of the touch functional layer.

As shown in FIG. 1, in the OLED display panel provided by the embodiment, the organic hardened layer 13, the glass substrate 12, and the transparent conductive layer 11 are the integrated structure. The glass substrate 12 is disposed between the organic hardened layer 13 and the transparent conductive layer 11. The ultra-thin glass substrate 12 is used to improve strength performance of an entire structure in an entire flexible structure, such as hardness, falling ball performance, and other strength properties. The organic hardened layer 13 on the other side of the glass substrate 12 can prevent the ultra-thin glass substrate 12 from being subjected to a direct mechanical impact, thereby protecting the glass substrate 12. In addition, the glass substrate 12 as a base material of the transparent conductive layer 11 can effectively improve stability of the touch circuit disposed on the transparent conductive layer 11.

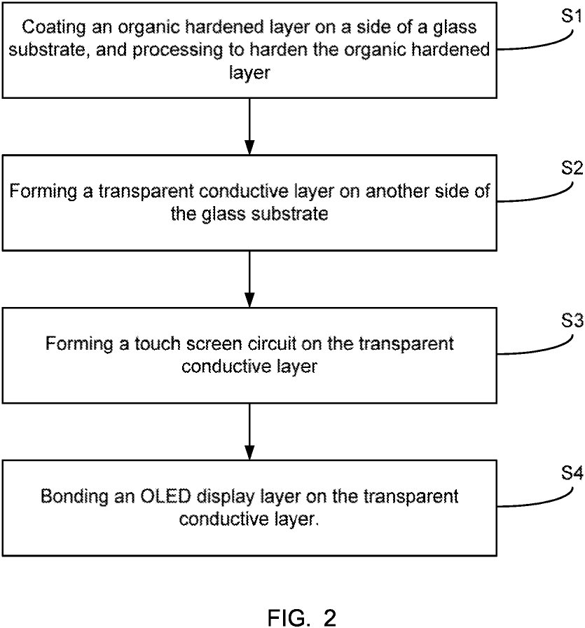

Shown in FIG. 2 is a flowchart of a manufacturing method of the OLED display panel according to an embodiment of the present invention, comprises following steps:

S1, coating an organic hardened layer on a side of a glass substrate, and processing to harden the organic hardened layer.

Wherein the glass substrate uses ultra-thin, high transmittance, bendable glass as a base material. The organic hardened layer is coated on one surface of the glass substrate using a coating technology, and then the organic hardened layer is hardened by a technology such as heating and UV light. The material of the organic hardened layer comprises the acrylic material or the siloxane-based material. The organic material such as the acrylic material or the siloxane-based material has the certain hardness after being hardened by the hardening technology, which can prevent the ultra-thin glass substrate from being subjected to a direct impact and can well protect the ultra-thin glass substrate. The thickness of the organic hardened layer can be set to range from 10 µm to 100 µm, so that the organic hardened layer has the certain strength and can effectively protect the ultra-thin glass substrate.

S2, forming a transparent conductive layer on another side of the glass substrate.

Wherein the transparent conductive layer is on the other side of the glass substrate opposite to the organic hardened layer. The transparent conductive material having the certain thickness is sputtered on the other side of the glass substrate by the deposition technology or sputtering technology to form the transparent conductive layer. The transparent conductive layer is made of indium tin oxide (ITO) material or other transparent conductive materials. The thickness of the transparent conductive layer is controlled between 1 µm and 10 µm, which is beneficial for realizing touch functionalization.

S3, forming a touch screen circuit on the transparent conductive layer.

Wherein the touch circuit layer is formed on the transparent conductive layer to realize the touch function, and the ultra-thin glass substrate and the touch circuit can be integrated. Through the integrated structure to achieve the thinning of the overall structure, the use of the adhesive layers and the number of the interfaces can also be reduced, greatly improving stability of the structure.

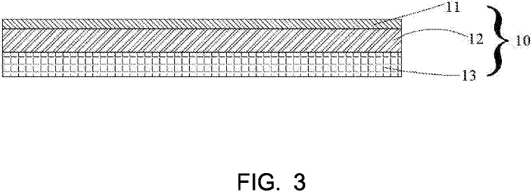

Shown in FIG. 3 is a schematic structural view of the substrate 10 provided by an embodiment of the present invention. The substrate 10 comprises the glass substrate 12, the organic hardened layer 13, and the transparent conductive layer 11. The organic hardened layer 13, the glass substrate 12, and the transparent conductive layer 11 are the integrated structure. The glass substrate 12 is disposed between the organic hardened layer 13 and the transparent conductive layer 11. The thickness of the organic hardened layer 13 ranges from 10 µm to 100 µm, and the thickness of the transparent conductive layer 11 ranges from 1 µm to 10 µm.

S4, bonding an OLED display layer on the transparent conductive layer.

Specifically, the transparent conductive layer in the substrate is bonded to the OLED display layer, or the transparent conductive layer in the substrate is laminated with the OLED display layer.

According to the OLED display panel and the manufacturing method thereof provided by the embodiment of the present invention, by using the ultra-thin glass substrate, the organic hardened layer and the transparent conductive layer are respectively formed on both sides of the glass substrate, thereby realizing the integrated structure of a cover plate, an ultra-thin glass, and a touch screen. The ultra-thin glass in the flexible structure can improve the strength performance of the entire structure, the organic hardened layer on one side of the glass can protect the ultra-thin glass from being subjected to a direct mechanical impact, and the glass substrate as the base material of the transparent conductive layer can effectively improve the stability of the touch circuit disposed on the transparent conductive layer. Through the integrated structure to achieve the thinning of the overall structure, the use of the adhesive layers and the number of the interfaces can also be reduced, greatly improving the stability of the structure.

The OLED display panel and the manufacturing method thereof provided in the embodiments of the present invention have been described in detail above. Specific examples are used in this article to explain the principle and implementation of this application. The descriptions of the above embodiments are only used to help understand the technical solution of this application and its core ideas. Those of ordinary skill in the art should understand that they can still modify the technical solutions described in the foregoing embodiments, or equivalently replace some of the technical features. These modifications or replacements do not depart from the scope of the technical solutions of the embodiments of the present application.

What is claimed is:

1. An organic light-emitting diode (OLED) display panel, comprising:
an OLED display layer; and
a substrate bonded to the OLED display layer;
wherein the substrate comprises a glass substrate, an organic hardened layer, and a transparent conductive layer, the organic hardened layer is disposed on a first side of the glass substrate, the transparent conductive layer is disposed on a second side of the glass substrate, and the first side of the glass substrate is opposite to the second side of the glass substrate;
wherein the organic hardened layer, the glass substrate, and the transparent conductive layer are an integrated structure; and
wherein a thickness of the transparent conductive layer ranges from 1 µm to 10 µm, and a thickness of the organic hardened layer ranges from 10 µm to 100 µm.

2. The OLED display panel as claimed in claim 1, further comprising a touch screen circuit disposed on the transparent conductive layer.

3. The OLED display panel as claimed in claim 1, wherein a material of the organic hardened layer comprises acrylic material or siloxane-based material.

4. The OLED display panel as claimed in claim 1, wherein the transparent conductive layer is bonded to the OLED display layer.

5. An organic light-emitting diode (OLED) display panel, comprising:
an OLED display layer; and
a substrate bonded to the OLED display layer;
wherein the substrate comprises a glass substrate, an organic hardened layer, and a transparent conductive layer, the organic hardened layer is disposed on a first side of the glass substrate, the transparent conductive layer is disposed on a second side of the glass substrate, and the first side of the glass substrate is opposite to the second side of the glass substrate; and
wherein the organic hardened layer, the glass substrate, and the transparent conductive layer are an integrated structure.

6. The OLED display panel as claimed in claim 5, further comprising a touch screen circuit disposed on the transparent conductive layer.

7. The OLED display panel as claimed in claim 5, wherein a thickness of the transparent conductive layer ranges from 1 µm to 10 µm.

8. The OLED display panel as claimed in claim 5, wherein a thickness of the organic hardened layer ranges from 10 µm to 100 µm.

9. The OLED display panel as claimed in claim 8, wherein a material of the organic hardened layer comprises acrylic material or siloxane-based material.

10. The OLED display panel as claimed in claim 5, wherein the transparent conductive layer is bonded to the OLED display layer.

11. A manufacturing method of an organic light-emitting diode (OLED) display panel, comprising following steps:
coating an organic hardened layer on a side of a glass substrate, and processing to harden the organic hardened layer;
forming a transparent conductive layer on another side of the glass substrate;
forming a touch screen circuit on the transparent conductive layer; and
bonding an OLED display layer on the transparent conductive layer.

12. The manufacturing method of the OLED display panel as claimed in claim 11, wherein a thickness of the organic hardened layer ranges from 10 µm to 100 µm.

13. The manufacturing method of the OLED display panel as claimed in claim 11, wherein a thickness of the transparent conductive layer ranges from 1 µm to 10 µm.

14. The manufacturing method of the OLED display panel as claimed in claim 11, wherein the organic hardened layer, the glass substrate, and the transparent conductive layer are an integrated structure, and the glass substrate is disposed between the organic hardened layer and the transparent conductive layer.
